(19) United States
(12) Patent Application Publication
(10) Pub. No.: US 2016/0365296 A1
(43) Pub. Date: Dec. 15, 2016

(54) Electronic Devices with Increased Creepage Distances

(71) Applicant: Infineon Technologies AG, Neubiberg (DE)

(72) Inventors: Ralf Otremba, Kaufbeuren (DE); Edward Fuergut, Dasing (DE); Christian Kasztelan, Munich (DE); Hsieh Ting Kuek, Melaka (MY); Teck Sim Lee, Melaka (MY); Sanjay Kumar Murugan, Malacca (MY); Lee Shuang Wang, Melaka (MY)

(21) Appl. No.: 15/176,952

(22) Filed: Jun. 8, 2016

(30) Foreign Application Priority Data
Jun. 9, 2015 (DE) 102015109073.2

(51) Int. Cl. H01L 23/31; H01L 21/56; H01L 21/48; H01L 23/495; H01L 23/29

(52) U.S. Cl. CPC H01L 23/3114; H01L 23/49568; H01L 23/293; H01L 23/49503; H01L 23/4952; H01L 23/49541; H01L 21/4825; H01L 21/565

(57) ABSTRACT

A device includes an encapsulation material and a first lead and a second lead protruding out of a surface of the encapsulation material. A recess extends into the surface of the encapsulation material. An elevation is arranged on the surface of the encapsulation material. The first lead protrudes out of the elevation.

### TECHNICAL FIELD

The disclosure relates, in general, to electronic devices. More particular, the disclosure relates to electronic devices having increased creepage distances.

### BACKGROUND

Electronic devices such as e.g. power semiconductors may be operated with high voltages. Here, the devices may need to comply with electrical insulation requirements in accordance with given safety standards. Electronic devices constantly have to be improved. In particular, it may be desirable to fulfill required safety standards without reducing the performance and the quality of the devices. In this regard, it may be particularly desirable to increase creepage distances of the devices. In addition, it may be desirable to reduce system costs and to provide higher power density.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1A schematically illustrates a top view of a device 100 in accordance with the disclosure.

FIG. 1B schematically illustrates a cross-sectional side view of the device 100.

FIG. 2A schematically illustrates a top view of a device 200 in accordance with the disclosure.

FIG. 2B schematically illustrates a cross-sectional side view of the device 200.

FIG. 2C schematically illustrates a bottom view of the device 200.

FIGS. 3A to 3C schematically illustrate cross-sectional side views of devices 300A to 300C in accordance with the disclosure.

### DETAILED DESCRIPTION

In the following detailed description, reference is made to the accompanying drawings in which are shown by way of illustration specific aspects in which the disclosure may be practiced. In this regard, directional terminology, such as e.g. “top”, “bottom”, “front”, “back”, may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

As employed in this specification, the terms “connected”, “coupled”, “electrically connected” and/or “electrically coupled” may not necessarily mean that elements must be directly connected or coupled together. Intervening elements may be provided between the “connected”, “coupled”, “electrically connected” or “electrically coupled” elements.

Further, the word “over” used with regard to e.g. a material layer formed or located “over” a surface of an object may be used herein to mean that the material layer may be located (e.g. formed, deposited) “directly on”, e.g. in direct contact with, the implied surface. The word “over” used with regard to e.g. a material layer formed or located “over” a surface may also be used herein to mean that the material layer may be located (e.g. formed, deposited) “indirectly on” the implied surface with e.g. one or more additional layers being arranged between the implied surface and the material layer.

Further, the words “perpendicular” and “parallel” may be used herein with regard to a relative orientation of two or more components. It is understood that these terms may not necessarily mean that the specified geometric relation is realized in a perfect geometric sense. Instead, fabrication tolerances of the involved components may need to be considered in this regard. For example, if two surfaces of an encapsulation material of a semiconductor package are specified to be perpendicular (or parallel) to each other, an actual angle between these surfaces may deviate from an exact value of 90 (or 0) degrees by a deviation value that may particularly depend on tolerances that may typically occur when applying techniques for fabricating a housing made of the encapsulation material.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures. In addition, the features of the various exemplary aspects described herein may be combined with each other, unless specifically noted otherwise.

The devices described herein may include one or more semiconductor chips of arbitrary type. In general, the semiconductor chips may e.g. include integrated electrical, electrooptical or electromechanical circuits, passives. The integrated circuits may generally be designed as logic integrated circuits, analog integrated circuits, mixed signal integrated circuits, power integrated circuits, memory circuits, integrated passives, microelectromechanical systems. In one example, the semiconductor chips may be made of an elemental semiconductor material, for example Si. In a further example, the semiconductor chips may be made of a compound semiconductor material, for example GaN, SiC, SiGe, GaAs. In particular, the semiconductor chips may include one or more power semiconductors. The power semiconductor chips may be configured as e.g. diodes, power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), super junction devices, power bipolar transistors. In one example, the semiconductor chips may have a vertical structure, i.e. electrical currents may substantially flow in a direction perpendicular to the main faces of the semiconductor chips. In a further example, the semiconductor chips may have a lateral structure, i.e. electrical currents may substantially flow in a direction parallel to a main face of the semiconductor chips.

The semiconductor chips may be packaged. In this regard, the terms “semiconductor device” and “semiconductor package” as used herein may be interchangeably used. For example, semiconductor packages may be leaded and through-hole packages, SMD (surface mounted devices), IPM (Intelligent Power Modules), etc. In particular, a semiconductor package may be a semiconductor device including an encapsulation material that may at least partly cover (or embed or encapsulate) one or more components of the semiconductor device. The encapsulation material may be electrically insulating and may form an encapsulation body. The encapsulation material may include at least one of an epoxy, a glass fiber filled epoxy, a glass fiber filled polymer, an imide, a filled or non-filled thermoplastic polymer material, a filled or non-filled duroplastic polymer material, a filled or non-filled polymer blend, a thermosetting material, a mold compound, a glob-top material, a laminate material. Various techniques may be used to encapsulate components of the device with the encapsulation material, for example at least one of compression molding, injection molding, powder molding, liquid molding, transfer molding, lamination.

The devices described herein may include a carrier over which one or more electronic components such as e.g. semiconductor chips may be arranged. The carrier may be manufactured from a metal, an alloy, a dielectric, a plastic, a ceramic, or combinations thereof. The carrier may have a homogeneous structure, but may also provide internal structures like conducting paths with an electric redistribution function. Examples for a carrier are a leadframe, a ceramic substrate including one or more redistribution layers, a PCB (Printed Circuit Board), a DCB (Direct Copper Bonded) substrate, an IMS (Insulated Metal Substrate), a hybrid ceramic substrate. A leadframe may be structured such that diepads (or chip islands) and leads may be formed. During a fabrication of a device, the diepads and the leads may be connected to each other. The diepads and the leads may also be made from one piece. The diepads and the leads may be connected among each other by connection means with the purpose of separating some of the diepads and the leads in the course of the fabrication. Here, separating the diepads and the leads may e.g. be carried out by at least one of mechanical sawing, a laser beam, cutting, stamping, milling, etching. In particular, a leadframe may be electrically conductive. For example, the leadframe may be entirely fabricated from metals and/or metal alloys, in particular at least one of e.g. copper, copper alloys, nickel, iron nickel, aluminum, aluminum alloys, steel, stainless steel. After encapsulating semiconductor chips of a semiconductor package with an encapsulation material, leads of a leadframe may protrude out of the formed housing and provide an electrical connection between the semiconductor chip and the outside of the housing. Here, the leads may protrude out of the encapsulation material on only one side of the housing or on multiple sides of the housing, for example opposite sides.

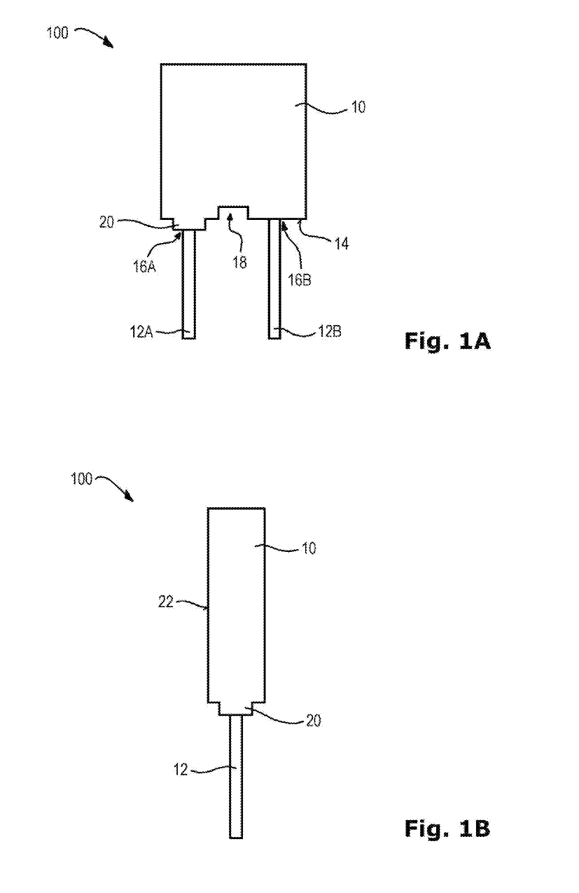

FIGS. 1A and 1B schematically illustrate respective views of a device 100 in accordance with the disclosure. In particular, FIG. 1A illustrates a top view of the device 100, and FIG. 1B illustrates a cross-sectional side view of the device 100. Due to the chosen perspectives, FIG. 1A may show components that are not shown by FIG. 1B and vice versa. In the example of FIGS. 1A-1B, the device 100 is illustrated in a general manner and may include further components that are not illustrated for the sake of simplicity. For example, the device 100 may additionally include one or more components of other devices in accordance with the disclosure.

The device 100 includes an encapsulation material 10 that may encapsulate an electronic component (not illustrated), for example a semiconductor chip. In particular, the encapsulation material 10 may form a housing to accommodate the electronic component. The device 100 further includes a first lead 12A and a second lead 12B that protrude out of a surface 14 of the encapsulation material 10. Hence, the surface 14 of the housing may include a first opening 16A and a second opening 16B configured to accommodate the first lead 12A and the second lead 12B, respectively. The surface 14 of the encapsulation material 10 may define a plane. The device 100 further includes a recess 18 extending into the surface 14 of the encapsulation material 10. In the example of FIGS. 1A-1B, the recess 18 may be particularly arranged between the first lead 12A and the second lead 12B, i.e. between the first opening 16A and the second opening 16B of the housing. In further examples, the recess 18 may be arranged to the left of the first lead 12A or to the right of the second lead 12B. In particular, the recess 18 may extend below the level of the plane defined by the surface 14. The device 100 further includes an elevation 20 arranged on the surface 14 of the encapsulation material 10, wherein the first lead 12A protrudes out of the elevation 20. In particular, the elevation 20 may extend above the level of the plane defined by the surface 14. The elevation 20 may particularly form a collar surrounding the first lead 12A.

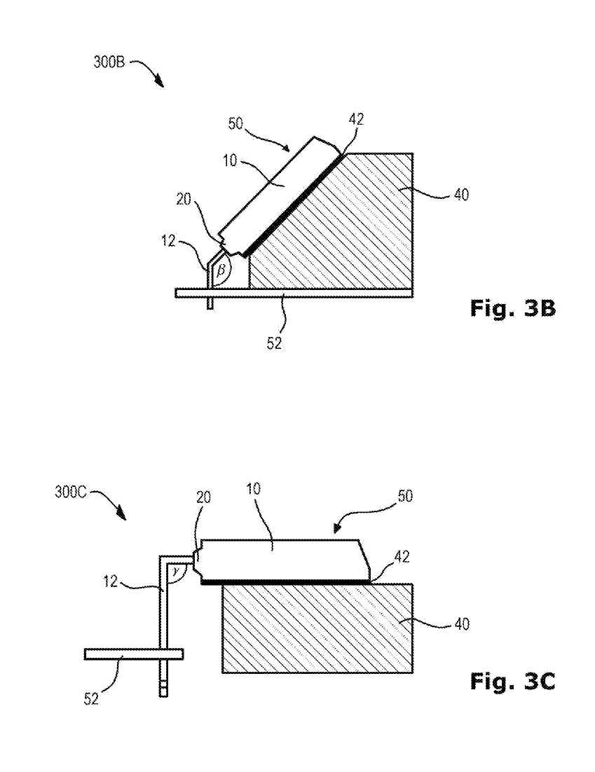

During an operation of the device 100, a tracking between electrically conductive components of the device 100 may occur. In this connection, a creepage distance may be defined as the shortest path between two conductive materials measured along the surface of an isolator arranged in between. Maintaining a certain creepage distance may address the risk of tracking failures over lifetime. The design of the device 100 may result in creepage distances that may reduce the risk of tracking failures. In a first example, the recess 18 may result in an increased creepage distance between the first lead 12A and the second lead 12B along the surface 14 of the encapsulation material 10, thus reducing a risk of tracking failure between the first lead 12A and the second lead 12B. In a second example, the elevation 20 may result in an increased creepage distance between the first lead 12A and a heatsink (not illustrated) that may be arranged over a main surface 22 of the encapsulation material 10. In this regard, devices in accordance with the disclosure may not necessarily require a special design of an employed heatsink taking into account the issue of sufficient creepage distances. Rather, a usage of recesses and/or elevations as discussed herein may allow a usage of standard heatsink as e.g. shown in FIGS. 3A to 3C.

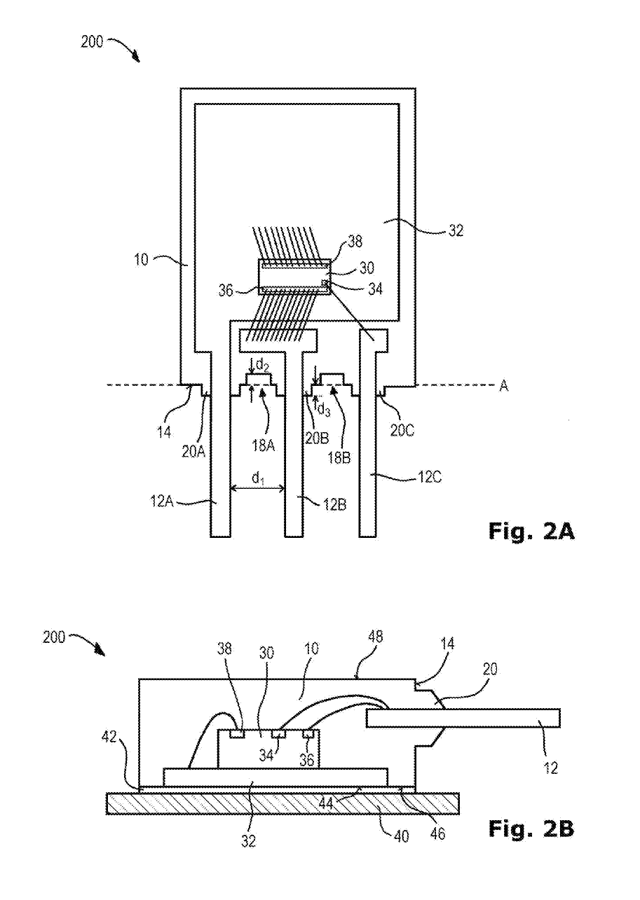

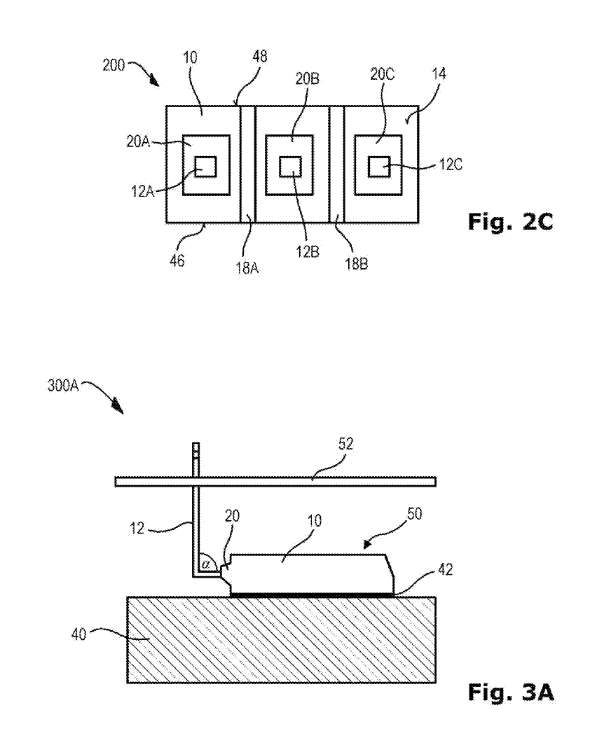

FIGS. 2A to 2C schematically illustrate respective views of a device 200 in accordance with the disclosure. In particular, FIG. 2A illustrates a top view of the device 200, FIG. 2B illustrates a cross-sectional side view of the device 200, and FIG. 2C illustrates a bottom view of the device 200. Due to the chosen perspectives, a figure may show components that are not shown by the respective other figures and vice versa. The device 200 may be seen as a more detailed implementation of the device 100 such that details of the device 200 described below may be likewise applied to the device 100.

The device 200 may include a semiconductor chip 30 that may be mounted over a carrier, for example a leadframe including a diepad 32. The semiconductor chip 30 may include a gate electrode 34, a source electrode 36 and a drain electrode 38. FIGS. 2A-2C shows an example of a device including a power transistor chip. However, it is to be noted that the illustrated example is in no way limiting and that further examples may be based on arbitrary other electronic components. The device 200 may further include multiple leads 12A to 12C that may also be a part of the leadframe. In FIG. 2B, not all of the leads 12A to 12C are visible due to the chosen perspective. Here, the plurality of leads 12A to 12C is denoted by a single reference sign 12. The device 200 may further include an encapsulation material 10 and a heatsink 40. The heatsink 40 may be seen as a part of the device 200 or not. In addition, an electrically insulating and thermally conductive layer or pad 42 may be arranged between the encapsulation material 10 and the heatsink 40.

The gate electrode 34, the source electrode 36 and the drain electrode 38 may be arranged over a main surface of the semiconductor chip 30 facing away from the diepad 32. The drain electrode 38 may be electrically connected to the first lead 12A and the diepad 32, the source electrode 36 may be electrically connected to the second lead 12B, and the gate electrode 34 may be electrically connected to the third lead 12C. The leads and the electrodes may be electrically coupled via electrically conductive elements of the device 200 as illustrated in FIGS. 2A-2C. The electrically conductive elements may correspond to wires and/or clips. In the example of FIGS. 2A-2C, the electrically conductive elements may correspond to wires illustrated by solid lines. Since the drain electrode 38 may be electrically connected to the diepad 32 arranged on the bottom side of the semiconductor chip 30, the illustrated arrangement may be referred to as drain down arrangement. However, it is to be noted that the illustrated arrangement is exemplary and other arrangements may be implemented. In a further example, the source electrode may be electrically connected to the diepad arranged on the bottom side of the semiconductor chip. Such arrangement may be referred to as source down arrangement. Possible arrangements may include a semiconductor chip having a lateral structure or a vertical structure.

The leads 12A to 12C may protrude out of the encapsulation material 10 such that electrical connections between the electrodes of the semiconductor chip 30 and components arranged outside of the encapsulation material 10 may be established. The leads 12A to 12C may be arranged in parallel such that the device 200 may e.g. be arranged over a PCB as exemplarily illustrated in FIGS. 3A to 3C. In the bottom view of FIG. 2C, the leads 12A to 12C are illustrated to have an exemplary cross section of rectangular form. However, in further examples the cross section of one or more of the leads 12A to 12C may also have an arbitrary other form, for example a circular form, a square form, a diamond form. A distance d₁ or pitch between two directly adjacent leads may lie in a range from about 200 micrometers to about 2 millimeters.

The diepad 32 may be at least partly embedded in the encapsulation material 10. In the example of FIGS. 2A-2C, the diepad 32 may be exposed from the encapsulation material 10 on its lower surface 44. In particular, the exposed lower surface 44 of the diepad 32 and the lower main surface 46 of the encapsulation material 10 may be flush, i.e. the surfaces may be arranged in a common plane. Due to the flush arrangement of the surfaces, the lower surface 44 of the diepad 32 may contact the heatsink 40, in particular in a common plane. In the example of FIGS. 2A-2C, one or more additional electrically insulating and thermally conductive layer(s) 42 (such as e.g. thermal grease, a thermal sheet, a phase change material) may be arranged between the diepad 32 and the heatsink 40. In a further example, the diepad 32 may be in direct contact with the heatsink 40. A surface area of the electrically insulating and thermally conductive layer 42 and a surface area of a footprint of the encapsulation material 10 when viewed in the top view may be equal in the example of FIGS. 2A-2C. However, in further examples the surface area of the electrically insulating and thermally conductive layer 42 may be greater than the surface area of a footprint of the encapsulation material 10.

The encapsulation material 10 may include at least one of an epoxy, a glass fiber filled epoxy, a glass fiber filled polymer, an imide, a filled or non-filled thermoplastic polymer material, a filled or non-filled duroplastic polymer material, a filled or non-filled polymer blend, a thermosetting material, a mold compound, a glob-top material, a laminate material. Filler particles may e.g. include or may be based on silicon nitride, silicon oxide, aluminum nitride, aluminum oxide, boron nitride, silicone, bismaleimide (BMI), cyanate ester. The encapsulation material 10 may include a surface 14 that may define a plane A (see dashed line in FIG. 2A). In particular, the plane A may be perpendicular to the drawing plane of FIG. 2A. A first recess 18A arranged between the first lead 12A and the second lead 12B may extend into the surface 14 of the encapsulation material 10, thereby increase a creepage distance between the first lead 12A and the second lead 12B. In a similar fashion, a second recess 18B arranged between the second lead 12B and the third lead 12C may extend into the surface 14 of the encapsulation material 10, thereby increasing a creepage distance between the second lead 12B and the third lead 12C. For example, one or both of the recesses 18A and 18B may have a depth d₂ lying in a range from about 100 micrometers to about 2 millimeters below the level of the plane A. In general, the geometric shape of the recesses 18A and 18B may be arbitrary. In the bottom view of FIG. 2C, each of the recesses 18A and 18B is illustrated to have the shape or footprint of a rectangle that may extend from the first main surface 46 of the encapsulation material 10 to a second main surface 48 of the encapsulation material. However, in further examples the footprints of the recesses 18A and 18B may have an arbitrary other form, for example the form of a circle, a diamond, a square.

A first elevation 20A may be arranged over the surface 14 of the encapsulation material 10, wherein the first lead 12A may protrude out of the first elevation 20A. In particular, the encapsulation material 10 and the first elevation 20A may be formed integrally from a same material. In this regard, the encapsulation material 10 and the first elevation 20A may be formed during a same manufacturing process. For example, the housing formed by the encapsulation material 10 may be produced by a molding process wherein the form of an employed mold tool may also include the shape of the first elevation 20A (and also the shape of e.g. the first recess 18A). The first elevation 20A may form a collar that may surround the first lead 12A. In one example, the collar may completely surround the first lead 12A. The first elevation 20A may increase a creepage distance between the first lead 12A and the heatsink 40. In addition, the device 200 may include one or more of a second elevation 20B and a third elevation 20C that may be similar to the first elevation 20A. For example, one or more of the elevations 20A to 20C may have a height d₃ lying in a range from about 100 micrometers to about 2 millimeters above the level of the plane A. In general, the geometric shape of the elevations 20A to 20C may be arbitrary. In the bottom view of FIG. 2C, each of the elevations 20A to 20C is illustrated to have the shape or footprint of a rectangle. However, in further examples the footprints of the elevations 20A to 20C may have an arbitrary other form, for example the form of a circle, a diamond, a square. In the side view of FIG. 2B, not all of the elevations 20A to 20C may be visible due to the chosen perspective. Here, the elevations 20 are illustrated to have an exemplary trapezoidal form. However, in further examples of this perspective, the elevations 20 may have an arbitrary other form, for example the form of a rectangle, a triangle, a square.

FIGS. 3A to 3C schematically illustrate respective cross-sectional side views of devices 300A to 300C in accordance with the disclosure. In particular, FIGS. 3A to 3C illustrate various possibilities of mounting a semiconductor package in accordance with the disclosure on a PCB. The devices 300A to 300C may include a semiconductor package including one or more electronic components, for example a semiconductor chip. The electronic components may be covered by an encapsulation material and may thus be not visible.

The device 300A of FIG. 3A may include a semiconductor package 50 which may at least partly correspond to one of the devices 100 and 200 of FIGS. 1 and 2. The semiconductor package 50 may include an encapsulation material 10 and leads 12 protruding out of the encapsulation material 10. A heatsink 40 may be attached to the semiconductor package 50, wherein an electrically insulating layer 42 may be arranged between the encapsulation material 10 and the heatsink 40. The heatsink 40 may be regarded as a part of the device 300A or not. The semiconductor package 50 may be mounted on a PCB 52, wherein an electrical connection between electronic components of the semiconductor package 50 and the PCB 52 may be provided via the leads 12. In the example of FIG. 3A, the leads 12 may be bent in an upper direction. A bending angle α may be about 90 degrees and, more general, may lie in a range from about 85 degrees to about 95 degrees. The mounting of the semiconductor package 50 as illustrated in FIG. 3A may correspond to a conventional mounting for a high power equipment and a large heat sink.

The devices 300B and 300C may include similar components as the device 300A, but may be mounted on the PCB 52 in a different fashion. In the example of FIG. 3B, the semiconductor package 50 may be mounted on a surface of the heatsink 40 that may be inclined with an angle of about 45 degrees. The leads 12 may thus be bent with a bending angle β which may be about 45 degrees and, more general, may lie in a range from about 40 degrees to about 50 degrees. In the example of FIG. 3C, the leads 12 may be bent in a lower direction, wherein a bending angle y may be about 90 degrees and, more general, may lie in a range from about 85 degrees to about 95 degrees.

In FIGS. 3A to 3C, the encapsulation material 10 may include elevations 20 and recesses (not illustrated) providing increased creepage distances between the leads 12 and the heatsink 40 as previously discussed. Hence, the devices 300A to 300C may not necessarily require a special design of the heatsink 40 taking into account the issue of sufficient creepage distances. Rather, a design of the encapsulation material 10 in accordance with the disclosure may allow usage of a standard heatsink as shown in FIGS. 3A to 3C.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the term “exemplary” is merely meant as an example, rather than the best or optimal. It is also to be appreciated that features and/or elements depicted herein are illustrated with particular dimensions relative to each other for purposes of simplicity and ease of understanding, and that actual dimensions may differ substantially from that illustrated herein.

Although specific aspects have been illustrated and described herein, it will be appreciated by those of ordinary skill in the art that a variety of alternate and/or equivalent implementations may be substituted for the specific aspects shown and described without departing from the concept of the disclosure. This application is intended to cover any adaptations or variations of the specific aspects discussed herein. Therefore, it is intended that this disclosure be limited only by the claims and the equivalents thereof.

What is claimed is:

1. A device, comprising:
an encapsulation material;
a first lead and a second lead protruding out of a surface of the encapsulation material;
a recess extending into the surface of the encapsulation material; and
a first elevation arranged on the surface of the encapsulation material, wherein the first lead protrudes out of the first elevation.

2. The device of claim 1, wherein the recess is arranged between the first lead and the second lead.

3. The device of claim 1, further comprising:
a second elevation arranged on the surface of the encapsulation material, wherein the second lead protrudes out of the second elevation.

4. The device of claim 3, wherein the first elevation and the second elevation are of similar shape and dimension.

5. The device of claim 1, wherein the surface of the encapsulation material defines a plane and the recess has a depth lying in a range from 100 micrometers to 2 millimeters below the level of the plane.

6. The device of claim 1, wherein the surface of the encapsulation material defines a plane and the first elevation has a height lying in a range from 100 micrometers to 2 millimeters above the level of the plane.

7. The device of claim 1, wherein the first elevation forms a collar surrounding the first lead.

8. The device of claim 1, wherein at least one of the recess and the first elevation has a rectangular shape.

9. The device of claim 1, wherein the recess extends from a first main surface of the encapsulation material to a second main surface of the encapsulation material.

10. The device of claim 1, wherein the encapsulation material and the first elevation are formed integrally from a same material.

11. The device of claim 1, wherein the encapsulation material comprises at least one of an epoxy, a glass fiber filled epoxy, a glass fiber filled polymer, an imide, a filled or non-filled thermoplastic polymer material, a filled or non-filled duroplastic polymer material, a filled or non-filled polymer blend, a thermosetting material, a mold compound, a glob-top material, and a laminate material.

12. The device of claim 1, wherein a spacing between the first lead and the second lead lies in a range from 200 micrometers to 2 millimeters.

13. The device of claim 1, further comprising:
a carrier; and
a semiconductor chip arranged over a first surface of the carrier,
wherein a second surface of the carrier opposite the first surface is exposed from the encapsulation material.

14. The device of claim 13, further comprising:
a heatsink arranged over the second surface of the carrier.

15. The device of claim 14, further comprising:
an electrically insulating and thermally conductive layer arranged between the encapsulation material and the heat sink.

16. The device of claim 1, further comprising:
a semiconductor chip at least partly covered by the encapsulation material,
wherein at least one of the first lead and the second lead is electrically coupled to the semiconductor chip.

17. A device, comprising:
an encapsulation material;
a first lead and a second lead protruding out of a surface of the encapsulation material;
a recess extending into the surface of the encapsulation material; and
a first collar arranged on the surface of the encapsulation material, wherein the first collar surrounds the first lead.

18. The device of claim 17, wherein the recess is arranged between the first lead and the second lead.

19. The device of claim 17, further comprising:
a second collar arranged on the surface of the encapsulation material, wherein the second collar surrounds the second lead.

20. A device, comprising:
a housing configured to accommodate a semiconductor chip, the housing comprising a surface with a first opening configured to accommodate a first lead and a second opening configured to accommodate a second lead;
a recess extending into the surface of the housing; and
an elevation arranged on the surface of the housing, wherein the elevation comprises the first opening.

21. The device of claim 20, wherein the recess is arranged between the first opening and the second opening.
